(19) United States
(12) Patent Application Publication
(10) Pub. No.: US 2015/0263027 A1
(43) Pub. Date: Sep. 17, 2015

(54) NONVOLATILE SEMICONDUCTOR STORAGE DEVICE

(71) Applicant: KABUSHIKI KAISHA TOSHIBA, Minato-ku (JP)

(72) Inventor: Wataru SAKAMOTO, Yokkaichi (JP)

(73) Assignee: KABUSHIKI KAISHA TOSHIBA, Minato-ku (JP)

(21) Appl. No.: 14/483,610

(22) Filed: Sep. 11, 2014

Related U.S. Application Data
(60) Provisional application No. 61/951,420, filed on Mar. 11, 2014.

(51) Int. Cl. H01L 27/115; H01L 29/51; H01L 29/423; H01L 29/792

(52) U.S. Cl. CPC H01L 27/11568; H01L 29/792; H01L 29/517; H01L 29/518; H01L 29/42344; H01L 29/513

(57) ABSTRACT

A nonvolatile semiconductor storage device is provided with a semiconductor substrate; a tunnel insulating film formed above the semiconductor substrate; a charge storing layer formed above the tunnel insulating film; a charge storing surface layer film being formed only above an upper surface of the charge storing layer and being provided with a metal film or a metal containing film having a work function higher than a work function of an n-type polysilicon (Si); an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and a control electrode formed above the interelectrode insulating film.

### CROSS-REFERENCE TO RELATED APPLICATION(S)

This application is based upon and claims the benefit of priority from U.S. Provisional Patent Application No. 61/951,420, filed on, Mar. 11, 2014 the entire contents of which are incorporated herein by reference.

### FIELD

Embodiments disclosed herein generally relate to a nonvolatile semiconductor storage device.

### BACKGROUND

A mass-storage nonvolatile semiconductor storage device for example is provide with multiplicity of memory cells and information is stored in these memory cells. A memory cell is generally provided with a tunnel insulating film formed above a semiconductor substrate, a charge storing layer formed above the tunnel insulating film, an insulating layer formed above the charge storing layer, and a control electrode formed above the insulating layer. Because multiplicity of such memory cells are formed above the semiconductor substrate, it is required to shrink the size of the memory cells in the surface direction of the semiconductor substrate. As a result, the upper end of the charge storing layer of the memory cell becomes pointed and facilitates electric field concentration at the upper end of the charge storing layer. This increased the leakage current between the control electrode and the charge storing layer and cause programming saturation.

### BRIEF DESCRIPTION OF THE DRAWINGS

FIG. 1 pertains to all of the embodiments and is one example of an electrical configuration diagram schematically illustrating the circuit configuration within a memory-cell region of a nonvolatile semiconductor storage device.

FIG. 2 pertains to all of the embodiments and is one example of a plan view schematically illustrating the layout of memory cells within the memory-cell region of the nonvolatile semiconductor storage device.

FIG. 3A pertains to a first embodiment and is one example of a vertical cross-sectional view taken along line 3A-3A of FIG. 2 and schematically illustrates a cross section of some of the structures within the memory-cell region.

FIG. 3B pertains to the first embodiment and is one example of a vertical cross-sectional view taken along line 3B-3B of FIG. 2 and schematically illustrates a cross section of some of the structures within the memory-cell region.

FIG. 3C pertains to the first embodiment and is one example of an energy band diagram of the interface of a charge storing layer and a control electrode.

FIGS. 4A, 5A, 6A, 7A, 8A, 9A, and 10A pertain to the first embodiment and are examples of vertical cross-sectional views schematically illustrating one phase of a manufacturing process flow of a portion taken along line 3A-3A of FIG. 2.

FIGS. 4B, 5B, 6B, 7B, 8B, 9B, and 10B pertain to the first embodiment and are examples of vertical cross-sectional views schematically illustrating one phase of a manufacturing process flow of a portion taken along line 3B-3B of FIG. 2.

FIG. 11A pertains to a second embodiment and is one example of a vertical cross-sectional view taken along line 3A-3A of FIG. 2 and schematically illustrates a cross section of some of the structures within the memory-cell region.

FIG. 11B pertains to the second embodiment and is one example of a vertical cross-sectional view taken along line 3B-3B of FIG. 2 and schematically illustrates a cross section of some of the structures within the memory-cell region.

FIG. 12A pertains to a third embodiment and is one example of a vertical cross-sectional view taken along line 3A-3A of FIG. 2 and schematically illustrates a cross section of some of the structures within the memory-cell region.

FIG. 12B pertains to the third embodiment and is one example of a vertical cross-sectional view taken along line 3B-3B of FIG. 2 and schematically illustrates a cross section of some of the structures within the memory-cell region.

FIG. 13A pertains to a fourth embodiment and is one example of a vertical cross-sectional view taken along line 3A-3A of FIG. 2 and schematically illustrates a cross section of some of the structures within the memory-cell region.

FIG. 13B pertains to the fourth embodiment and is one example of a vertical cross-sectional view taken along line 35-3B of FIG. 2 and schematically illustrates a cross section of some of the structures within the memory-cell region.

### DETAILED DESCRIPTION

One embodiment of a nonvolatile semiconductor storage device is provided with a semiconductor substrate; a tunnel insulating film formed above the semiconductor substrate; a charge storing layer formed above the tunnel insulating film; a charge storing surface layer film being formed only above an upper surface of the charge storing layer and being provided with a metal film or a metal containing film having a work function higher than a work function of an n-type polysilicon (Si); an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and a control electrode formed above the interelectrode insulating film.

One embodiment of a nonvolatile semiconductor storage device is provided with a semiconductor substrate; a tunnel insulating film formed above the semiconductor substrate; a charge storing layer formed above the tunnel insulating film; a charge storing surface layer film being formed only above an upper surface of the charge storing layer and being provided with a metal film; an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and a control electrode formed above the interelectrode insulating film, side surfaces of the charge storing layer facing the control electrode only via the interlayer insulating film, and the charge storing surface layer film formed only above an upper surface of the charge storing layer includes a ruthenium (Ru) film serving as the metal film.

One embodiment of a nonvolatile semiconductor storage device is provided with a semiconductor substrate; a tunnel insulating film formed above the semiconductor substrate; a charge storing layer formed above the tunnel insulating film; a charge storing surface layer film being formed only above an upper surface of the charge storing layer and being provided with a metal containing film; an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and a control electrode formed above the interelectrode insulating film, side surfaces of the charge storing layer facing the control electrode only via the interlayer insulating film, and the charge storing surface layer film formed only above an upper surface of the charge storing layer includes a tantalum nitride (TaN) film or a titanium nitride (TiN) film as the metal containing film.

Embodiments of a nonvolatile semiconductor storage device and a manufacturing method of the same are described hereinafter with reference to the drawings. In the drawings referred to in the following description, elements that are identical or similar are identified with identical or similar reference symbols. The drawings are schematic and thus, are not necessarily consistent with the actual correlation of thickness to planar dimensions and the actual thickness ratios between each of the layers. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. Further, convenience of explanation, directional terms such as up, down, left, right, high and low, as well as deep and shallow for describing the trenches are used in a relative context with respect to a rear side of the later described semiconductor substrate.

In the following description, XY coordinate system is used for convenience of explanation. In the coordinate system, the X direction and the Y direction each indicates a direction parallel to the surface of semiconductor substrate 1 and crosses with one another.

### First Embodiment

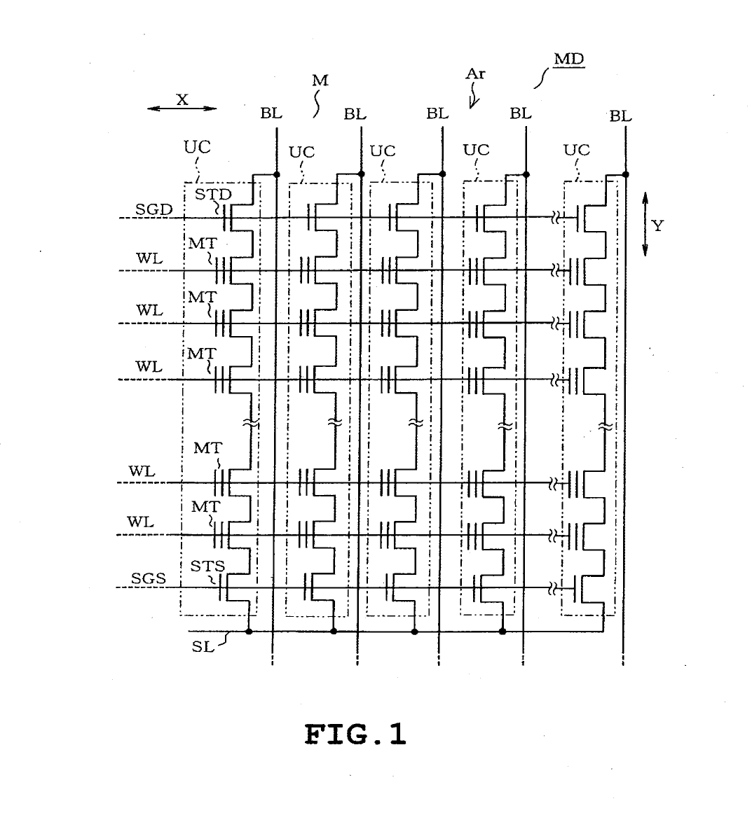

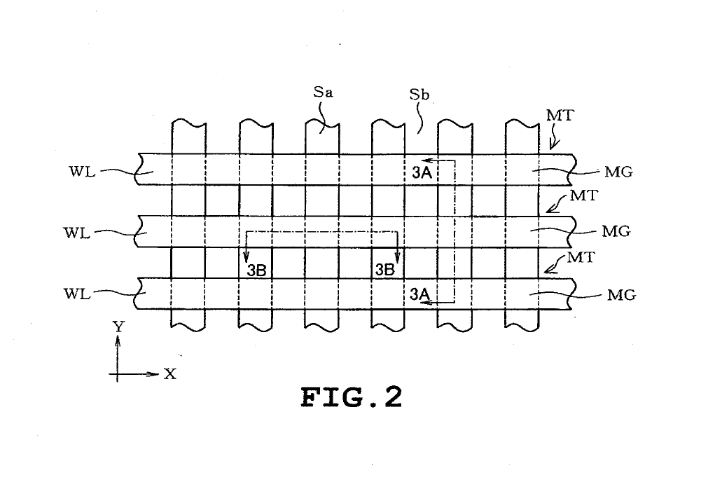

FIGS. 1 to 10B illustrate a first embodiment. FIG. 1 illustrates one example of an electrical configuration of the planar-type NAND flash memory device. FIG. 2 partially and schematically illustrates one example of structures disposed within a memory-cell region.

Flash memory device MD, which is one example of a nonvolatile semiconductor storage device, is provided with memory-cell array Ar including multiplicity of cell units UC arranged in a matrix within a memory-cell region M and a peripheral circuit (not shown) for driving memory-cell array Ar. Memory-cell array Ar includes multiplicity of cell units UC aligned in the X direction within memory-cell region M. Though FIG. 1 only illustrates a single block, multiple blocks are aligned in the Y direction in the actual structure with each block being configured by a cell-unit group containing multiple cell units UC.

Each cell unit UC is provided with a couple of select transistors STD and STS and multiple (64 for example) memory cells MT. Memory cells MT are series connected between select transistors STD and STS. Memory cells MT form a cell string. Either of the drain/source of select transistor STD is connected to bit line BL and the remaining other of the drain/source of select transistor STD is connected to either of the source/drain of memory cell MT disposed at one end of the cell string. The other end of the cell string is connected to the drain/source of select transistor STS and the remaining other of the drain/source of select transistor STS is connected to source line SL.

Further, as illustrated in FIG. 2, element regions Sa of memory cells MT are formed along the Y direction and are separated in the X direction. These element regions Sa are isolated from one another by element isolation regions Sb. Memory cells MT of cell units UC are connected in the X direction by a common word line WL.

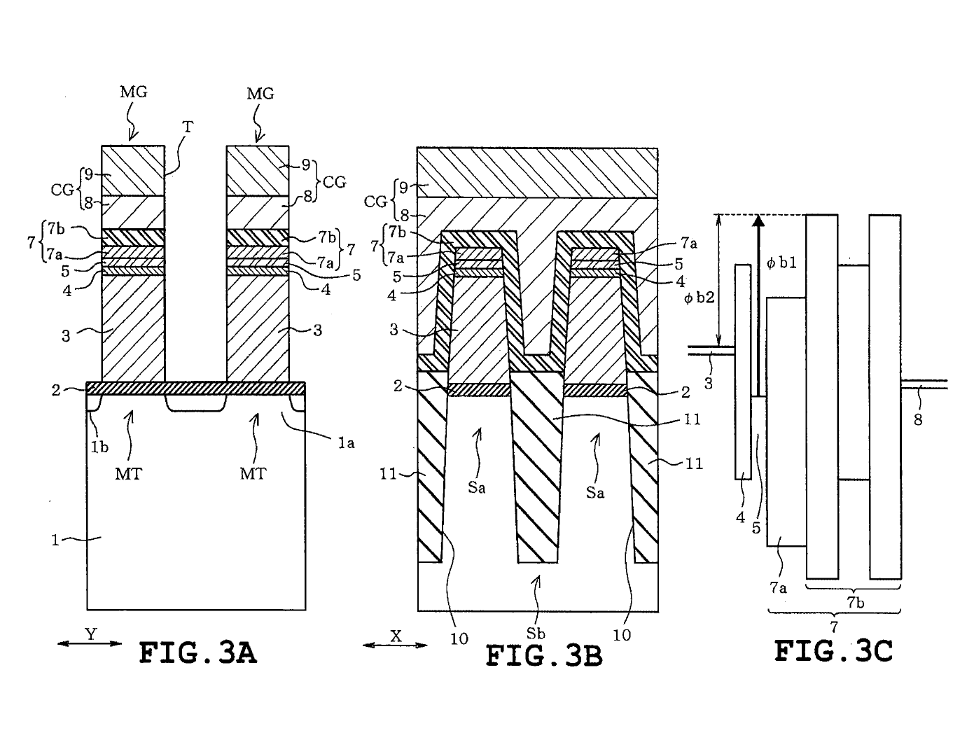

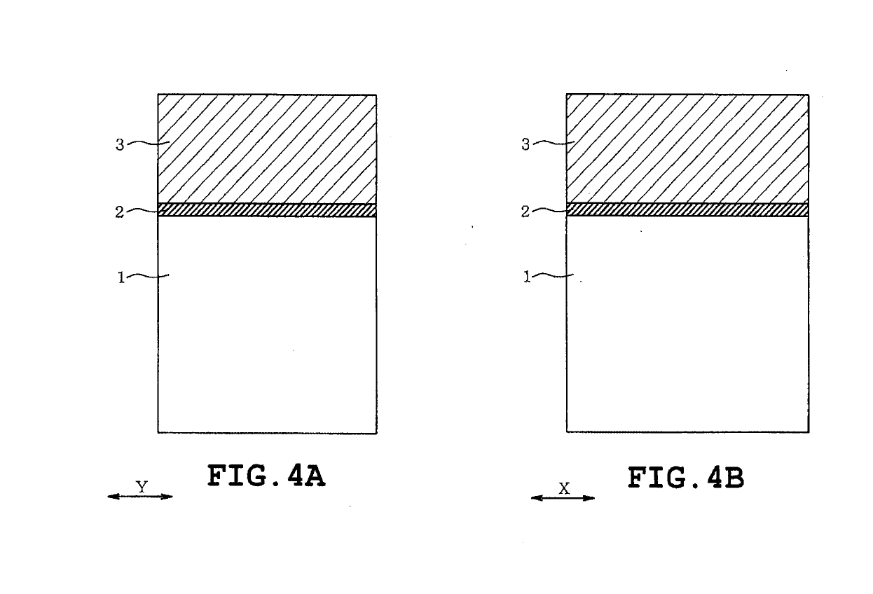

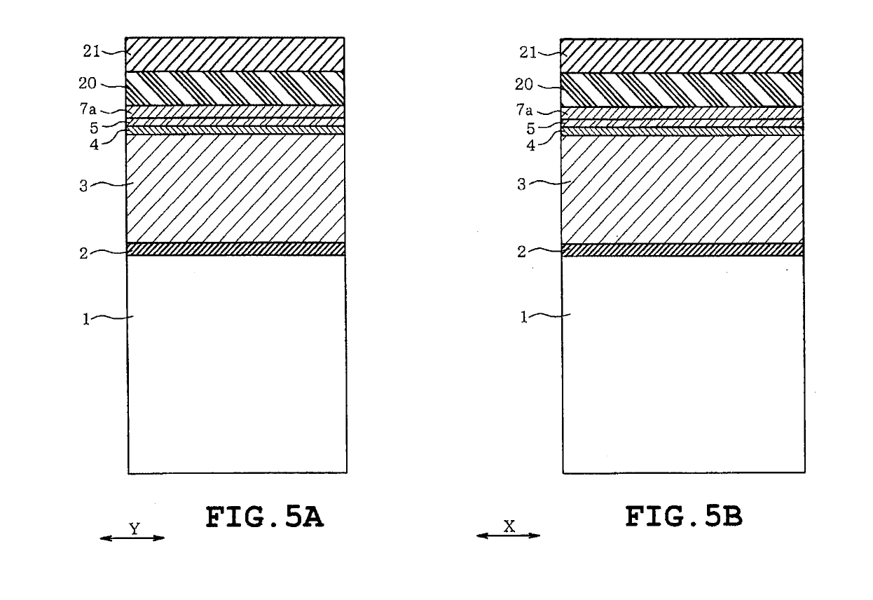

FIG. 3A schematically illustrates an example of a cross-sectional structure of the lengthwise direction of the channel of memory cells MT taken along line 3A-3A of FIG. 2. FIG. 3B schematically illustrates an example of a cross-sectional structure of the widthwise direction of the channel of memory cells MT taken along line 3B-3B of FIG. 2.

In the cross section illustrated in FIG. 3A, memory cells MT are aligned in the Y direction. Semiconductor substrate 1 is configured for example by a p-type monocrystal silicon substrate.

Each of memory cells MT are provided with gate MG and source/drain region 1b. Gate MG is formed above semiconductor channel 1a of semiconductor substrate 1 via tunnel insulating film 2. Source/drain region 1b is formed in the surface layer of semiconductor substrate 1 located in both sides of gate MG. Gates MG illustrated in FIG. 3A is isolated from one another by trench T which is formed along the direction normal to the page (X direction) of FIG. 3A.

Gate MG is configured by stacking charge storing layer 3, silicon nitride (SiN) film 4, ruthenium (Ru) film 5, interelectrode insulating film. 7, polysilicon film 8, and metal film 9 above tunnel insulating film 2. Tunnel insulating film 2 is configured by using a silicon oxide film for example. Tunnel insulating film 2 is formed in a thickness ranging for example from 6 to 8 [nm] which allows FN (Fouler-Nordheim: hereinafter referred to as FN) tunnel current to flow.

Charge storing layer 3 is formed in contact with the upper surface of tunnel insulating film. 2 and is formed of for example a polysilicon doped with p-type impurities (such as boron) or n-type impurities (such as phosphorous (F) or arsenic (As)). Charge storing layer 3 is formed in a thickness ranging for example from 50 to 100 [nm].

Silicon nitride film 4 is formed in contact with the upper surface of charge storing layer 3 and is formed in a predetermined thickness ranging for example from 1 to 2 [nm]. Ruthenium film 5 is formed in contact with the upper surface of silicon nitride film 4 and is formed in a thickness ranging for example from 1 to 3 [nm].

Interlayer insulating film 7 is provided with hafnium oxide film 7a and ONO (Oxide-Nitride-Oxide) film 7b. Hafnium oxide film 7a is formed in contact with only the upper surface of ruthenium film 5. Hafnium oxide film 7a is formed so that its thickness ranges for example from 5 to 10 [nm]. ONO film 7b is used as the upper layer film of interelectrode insulating film 7 in this example. ONO film 7b may be replaced by a silicon oxide (SiO) film, a silicon nitride (Sill) film, or a silicon oxynitride (SiON) film, or a stack of two or more of the foregoing films.

Polysilicon film 8 is formed in contact with the upper surface of ONO film 7b and is doped for example with p-type and/or n-type impurities. Metal film 9 is formed of for example a tungsten (W) film with titanium nitride (TiN) or tungsten nitride (WN) serving as a barrier film. Polysilicon film 8 and metal film 9 are configured as word line WL and control electrode CG. Word line (control electrode CG) may be formed of a p-type or an n-type polysilicon alone, or a stack of the polysilicon and a silicide layer, in which the metal provided above the polysilicon is silicided. Gate MG is configured as described above. An interlayer insulating film (not shown) is formed so as to cover gate MG but is not shown.

In the schematic cross section illustrated in FIG. 3B, element isolation trenches 10 are formed into semiconductor substrate 1. Element isolation trenches 10 are formed so as to isolate element region Sa, tunnel insulating film 2, charge storing layer 3, silicon nitride film 4, ruthenium film 5, and hafnium oxide film 7a in the X direction.

Element isolation trenches 10 are filled with element isolation films 11. Element isolation film 11 is formed of a silicon oxide film for example and protrudes upward higher than the upper surface of semiconductor substrate 1. Element isolation film 11 forms element isolation region Sb of an STI (Shallow Trench Isolation) structure.

Between element isolation films 11 adjacent in the X direction, tunnel insulating film 2 is formed above semiconductor channel 1a of semiconductor substrate 1. Element isolation film 11 is formed along both lower side surfaces of charge storing layer 3. Above tunnel insulating film 2, charge storing layer 3, silicon nitride film 4, ruthenium film 5, and hafnium oxide film 7a are formed one after another.

Interelectrode insulating film 7 is formed so as to cover tunnel insulating film 2, charge storing layer 3, silicon nitride film 4, and ruthenium film 5. Hafnium oxide film 7a serving as interelectrode insulating film 7 is also formed only above the upper surface of ruthenium film 5 in the cross section illustrated in FIG. 3B as well.

Interelectrode insulating film 7 is formed along the upper side surfaces of charge storing layer 3, the side surfaces of silicon nitride film 4, the side surfaces of ruthenium film 5, and the upper surface of element isolation film 11. Polysilicon film 8 and metal film 9 are formed one after the other above interelectrode insulating film 7. Further, charge storing layer 3, silicon nitride film 4, and ruthenium film 5 are formed in a so called tapered shape in which the width between the two X-direction side surfaces become narrower with elevation.

FIG. 3C schematically illustrates one example of an energy band diagram of the interface between charge storing layer 3 and polysilicon film 8 (control electrode CG). FIG. 3C indicates, for example, barrier height φb1 when a programming bias is applied, that is, when a bias is applied in the direction to cause flow of electric current from charge storing layer 3 to polysilicon film 8 (control electrode CG) with ruthenium film 5 disposed between charge storing layer 3 and control electrode CG. ONO film 7b in the band diagram of FIG. 3C employs a stacked structure of a silicon oxide (SiO) film, a silicon nitride (SiN) film, and a silicon oxide (SiO) film.

Ruthenium film 5 has a work function φm which is higher than the work function of an n-type polysilicon (φm=4.1 eV). Thus, it is possible to increase barrier height φb1 when ruthenium film 5 is disposed between charge storing layer 3 and interelectrode insulating film 7 as indicated in FIG. 3C.

For example, when a structure in which ruthenium film 5 is not disposed between silicon nitride film 4 and ONO film 7b is considered, energy barrier φb2 is equivalent to the difference of energy at the bottom of the conduction band of charge storing layer 3 and ONO film 7b. That is, barrier height φb1 is greater than energy barrier φb2 observed when there is no intervention of ruthenium film 5.

As a result, it is possible to reduce the leakage current flowing from the upper portion of charge storing layer 3 to control electrode CG. The leakage current can be reduced when barrier height b1 is high, because the leakage current flowing through interelectrode insulating film 7 behaves according to the current equation of EN tunnel current phenomenon. Formation of ruthenium film 5 increases barrier height ψb1 and relaxes the electric field applied to the upper portion of charge storing layer 3 and thereby reduces the leakage current flowing from the upper portion of charge storing layer 3 to control electrode CG.

A description will be given hereinafter on one example of a manufacturing process of a nonvolatile semiconductor storage device of the present embodiment. The following description will focus on the features of the manufacturing process, however, known process steps may be added between the process steps or some of the process steps described hereinafter may be removed as required. Further, the process steps may be rearranged if practicable.

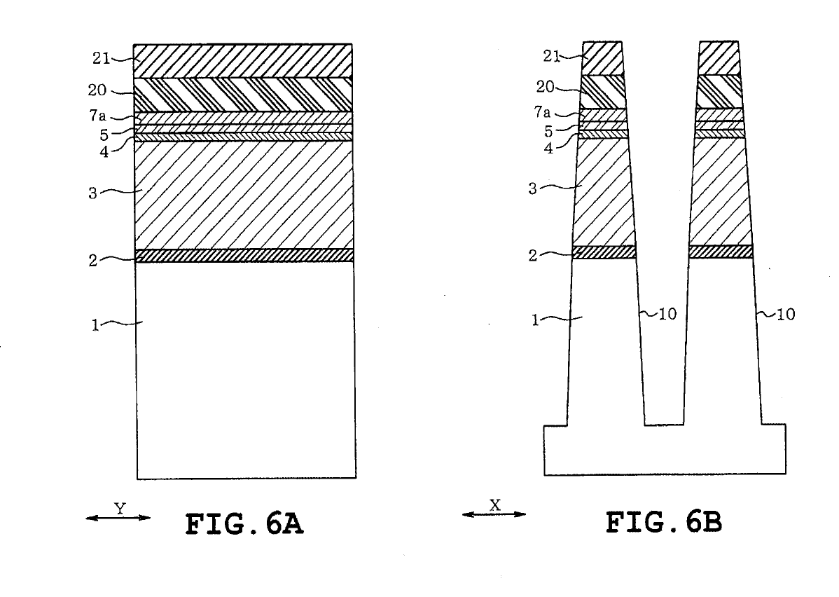

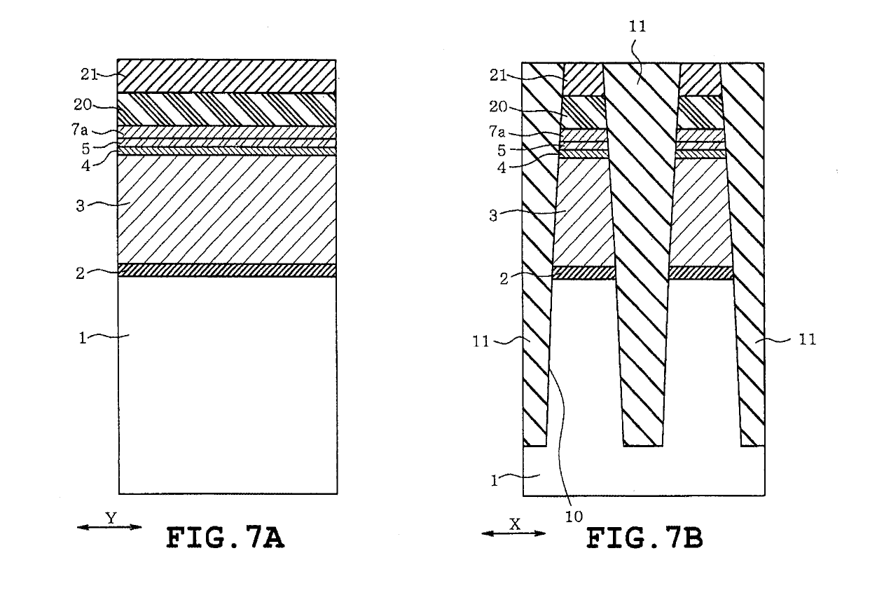

FIG. 4A to FIG. 10B schematically illustrate examples of cross sections at one phase of the manufacturing process flow. FIGS. 4A, 5A, BA, 7A, BA, 9A, and 10A suffixed by “A” are schematic cross-sectional views illustrating one phase of the manufacturing process flow of a structure corresponding to FIG. 3A. FIGS. 4B, 5B, BB, 7B, BB, 95, and 10B suffixed by “B” are schematic cross-sectional views illustrating one phase of the manufacturing process flow of a structure corresponding to FIG. 35.

First, as illustrated in FIGS. 4A and 4B, tunnel insulating film 2 is formed above semiconductor substrate 1. Tunnel insulating film 2 is formed in a thickness ranging for example from 6 to 9 nm when a silicon oxide film is used for example which is formed for example by thermal oxidation. Above tunnel insulating film 2, a polysilicon doped for example with p-type impurities (such as boron (B)) is deposited in a thickness ranging from 50 to 100 nm for example by CVD. The polysilicon serves as charge storing layer 3.

Charge storing layer 3 may be a p-type or an n-type. For example, when forming charge storing layer 3 with a polysilicon film doped with p-type impurities, p-type impurities may be introduced into the polysilicon film by for example doping impurities by ion implantation after depositing polysilicon free of impurities. Alternatively, the polysilicon film may be formed while doping p-type impurities.

As illustrated in FIGS. 5A and 5B, silicon nitride film 4, ruthenium film 5, hafnium oxide film 7a, mask silicon oxide film 20, and mask silicon nitride film 21 are formed one after another above charge storing layer 3. Silicon nitride film 4 is formed in a thickness ranging from 1 to 2 nm by for example CVD. Ruthenium film 5 is formed in a thickness ranging from 1 to 3 nm by for example CVD. Ruthenium film 5 may also be formed by for example PVD (Physical Vapor Deposition). Hafnium oxide film 7a is formed in a thickness ranging from 5 to 10 nm by for example CVD. Mask silicon oxide film 20 is formed in a thickness of approximately 10 nm by for example CVD. Mask silicon nitride film 21 is formed in a thickness ranging from 10 to 30 nm by for example CVD.

Then, a mask film (not shown) is formed further above mask silicon nitride film 21. The mask film, when being formed as an ordinary resist pattern obtained by lithography, may be formed by coating a resist above mask silicon nitride film 21 and patterning the resist by lithography.

When the X direction width of element region Sa is being narrowed beyond the critical dimension achievable by lithographic patterning based on normal photolithography, a double patterning is performed using the so called sidewall transfer technique after further forming multiple layers of mask films (not shown) above mask silicon nitride film 21. As a result, a mask film can be formed above mask silicon nitride film 21 in ½ of the X-direction width of the critical dimension achievable by normal patterning. The double patterning may be repeated twice in order to divide the mask film to ¼ in the X direction. Alternatively, a triple patterning may be performed to divide the mask film to ⅓ in the X direction. A description will not be given as it is irrelevant to the features of the present embodiment.

As illustrated in FIGS. 6A and 65, mask silicon nitride film 21 and mask silicon oxide film 20 are anisotropically etched by RIE (Reactive Ion Etching) using the mask film formed in the above described manner. Supposing that the X-direction critical dimension of the mask film formed by normal lithography is represented as 1, mask silicon nitride film 21 and mask silicon oxide film 20 can be formed in ½, ⅓, or ¼ of the X-direction critical dimension by for example using the mask formation techniques discussed above.

Then, hafnium oxide film 7a, ruthenium film 5, silicon nitride film 4, charge storing layer 3, tunnel insulating film 2, and the surface layer of semiconductor substrate 1 are anisotropically etched by RIE one after another using mask silicon nitride film 21 and mask silicon oxide film 20 as masks. Element isolation trench 10 is formed in the above described manner. At this stage of the manufacturing process flow, tunnel insulating film 2, charge storing layer 3, silicon nitride film 4, ruthenium film 5, and hafnium oxide film 7a in the cross section illustrated in FIG. 6B can be formed into a so-called tapered shape in which the width between the two X-direction side surfaces become narrower with elevation.

Element isolation trench 10 is formed so as to extend in the direction normal to the page of FIG. 6B (Y direction) and through hafnium oxide film 7a, ruthenium film 5, silicon nitride film 4, charge storing layer 3, and tunnel insulating film 2. Element isolation trench 10 reaches the upper portion of semiconductor substrate 1 and the bottom surface of element isolation trench 10 is lower than the upper surface of semiconductor substrate 1.

Next, as illustrated in FIG. 7A and FIG. 7B, element isolation film 11 is formed in element isolation trench 10. Element isolation film 11, when being formed of a silicon oxide film, may be formed by CVD and/or coating, etc. More specifically, element isolation trench 10 is filled by forming element isolation film 11 across the entire surface so that the upper surface of element isolation film 11 is higher above the upper surface of mask silicon nitride film 21. Then, element isolation film 11 is planarized by CMP (Chemical Mechanical Polishing) using the upper surface of mask silicon nitride film 21 as a stopper.

As illustrated in FIG. 8A and FIG. 8B, element isolation film 11 is etched back by for example RIE. Element isolation film 11 is etched back so that its upper surface is higher than the upper surface of tunnel insulating film 2 and lower than the upper surface of charge storing layer 3.

As illustrated in FIGS. 9A and 9B, mask silicon nitride film 21 is removed by hot phosphoric acid treatment. As illustrated in FIG. 10A and FIG. 10B, mask silicon oxide film 20 is removed by dilute hydrofluoric acid treatment.

As illustrated in FIGS. 3A and 3B, ONO film 7b is formed for example by CVD. It is possible to form ONO film 7b along side surfaces of each of charge storing layer 3, silicon nitride film 4, ruthenium film 5, and hafnium oxide film 7a, as well as along the upper surface of hafnium oxide film 7a and the upper surface of element isolation film 11. ONO film 7b may be replaced by a silicon oxide film, a silicon nitride film, a silicon oxynitride film, or a laminate of the foregoing films.

Further, polysilicon film 8 is formed above ONO film 7b. Polysilicon film 8 may be formed for example by CVD. Metal film 9 is formed above polysilicon film 8. Metal film 9 may be configured by tungsten (W) formed by PVD with titanium nitride (TiN) serving as a barrier film. Polysilicon film 8 and metal film 9 are formed so as to serve as control electrode CG and word line WL. However, control electrode CG and word line WL may be configured by metal film 9 alone.

A resist mask (not shown) is patterned above metal film 9 and the patterned resist mask is used as a mask to form trench T through stack of structures 3 to 9 illustrated in FIG. 3A. Trench T extends through metal film 9, polysilicon film 8, ONO film 7b, hafnium oxide film 7a, ruthenium film 5, silicon nitride film 4, and charge storing layer 3 to divide stack of structures 3 to 9. Gate MG is formed in the above described manner. In the present embodiment, tunnel insulating film 2 is formed so as to extend continuously in the Y direction below multiple gates MG. However, trench T may be formed so as to divide tunnel insulating film 2 in the Y direction.

Then, as illustrated in FIG. 3A and FIG. 3E, n-type impurities for example are introduced into the surface layer of semiconductor substrate 1 by ion implantation. The impurities are later subjected to thermal treatment to obtain source/drain regions 1b. Then, an interlayer insulating film formed of a silicon oxide film or the like is deposited and wirings or the like (neither shown) using structures such as a bit line contact, source line contact, source line, and bit line are formed though not described.

In the present embodiment, ruthenium film 5 is formed above the upper surface of charge storing layer 3. Thus, it is possible to increase barrier height φb1 and reduce the leakage current flowing through interelectrode insulating film 7. Further, hafnium oxide film 7a, ruthenium film 5, and silicon nitride film 4 are not formed along the side surfaces of charge storing layer 3. Thus, it is possible to reduce the aspect ratio when filling polysilicon film 8 and thereby improve the gap fill capability of polysilicon film 8. That is, a thin interelectrode insulating film 7 can be formed along the side surfaces of charge storing layer 3 and the margin obtained by thinning interelectrode insulating film 7 can be utilized for shrinking the pitch of element region Sa. It is thus, possible to achieve miniaturization.

### Second Embodiment

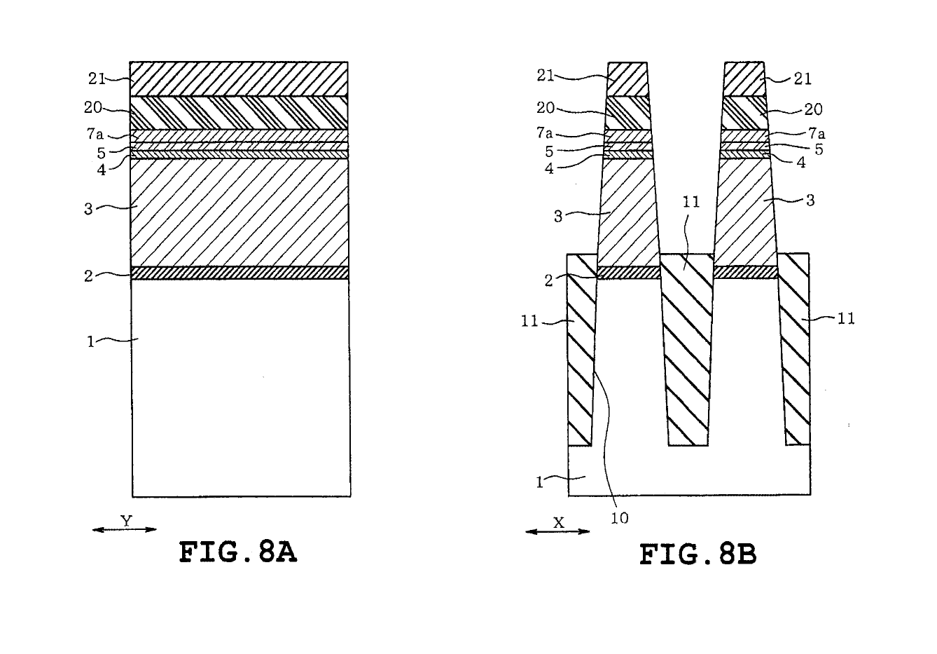

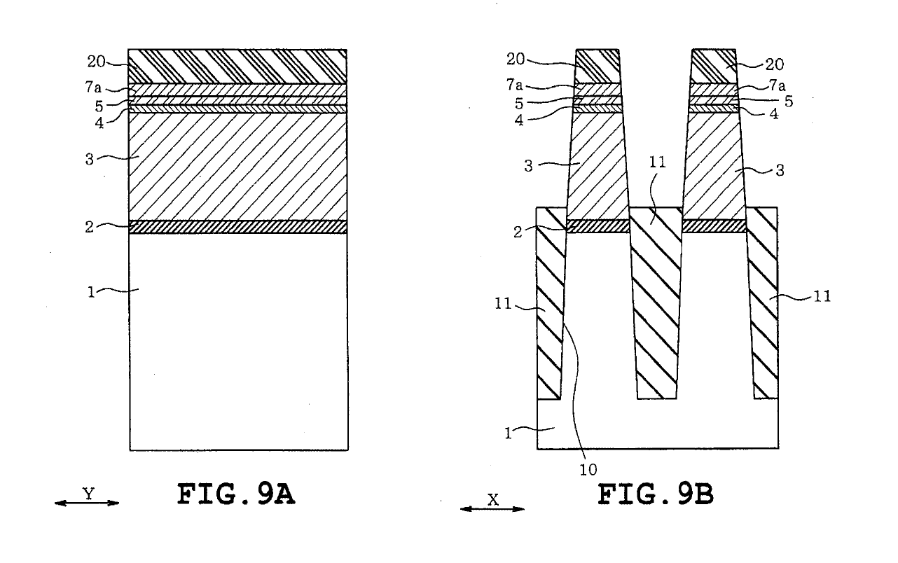

FIG. 11A and FIG. 11B illustrate a second embodiment. The structures of the present embodiment, as illustrated in FIG. 11A and FIG. 11B, have a stacked structure above tunnel insulating film 2 in which charge storing layer 3, ruthenium film 5, hafnium oxide film 7a, ONO film 7b, polysilicon film 8, and metal film 9 are formed one after another.

In this structure, ruthenium film 5 is formed in contact with the upper surface of charge storing layer 3 and silicon nitride film 4 of the first embodiment is not formed. The structures illustrated in FIGS. 11A and 11B can be obtained by eliminating the process step for forming silicon nitride film 4 from the manufacturing process of the first embodiment.

Because ruthenium film 5 is formed above the upper surface of charge storing layer 3, barrier height Vol can be increased and thereby reduce leakage current in this structure as well. The present embodiment is lower than the first embodiment by the thickness of silicon nitride film 4. Thus, element isolation region Sb can be formed easily.

### Third Embodiment

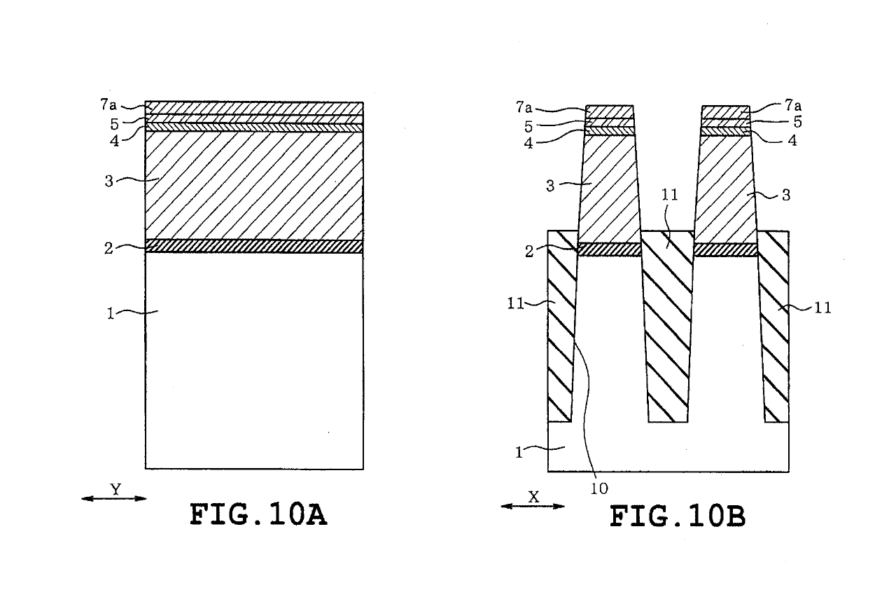

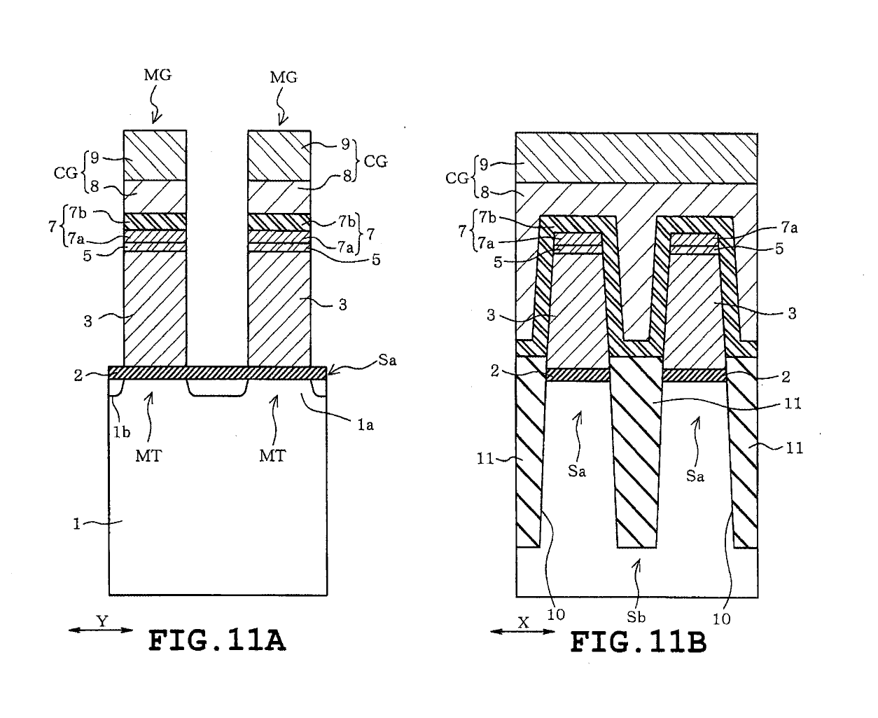

FIG. 12A and FIG. 12B illustrate a third embodiment. The structures of the present embodiment, as illustrated in FIG. 12A and FIG. 12B, have a stacked structure above tunnel insulating film 2 in which charge storing layer 3, ruthenium film 5, ONO film 7b, polysilicon film 8, and metal film 9 are formed one after another. In the present embodiment, ONO film 7b serves as the interelectrode insulating film.

In the present embodiment, ruthenium film 5 is formed in contact with the upper surface of charge storing layer 3 and ONO film 7b is formed in contact with the upper surface and the side surfaces of ruthenium film 5. Thus, silicon nitride film 4 and hafnium oxide film 7a in the first embodiment are not formed. The structures illustrated in FIGS. 12A and 12B can be obtained by eliminating the process step for forming silicon nitride film 4 and hafnium oxide film 7a from the manufacturing process of the first embodiment.

Because ruthenium film 5 is formed above the upper surface of charge storing layer 3, barrier height φb1 can be increased and thereby obtain the operation effect similar to those of the foregoing embodiments in this structure as well.

### Fourth Embodiment

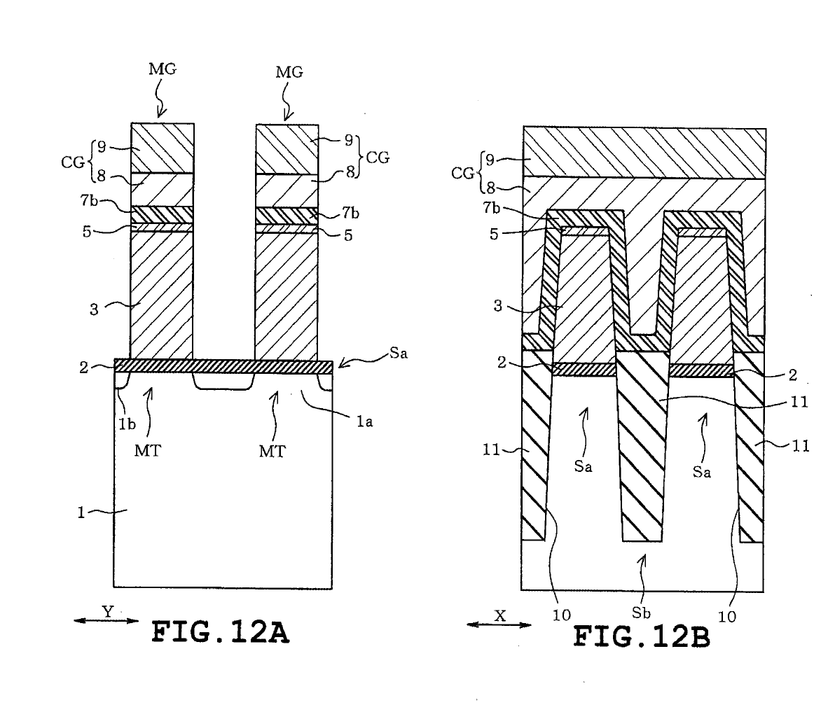

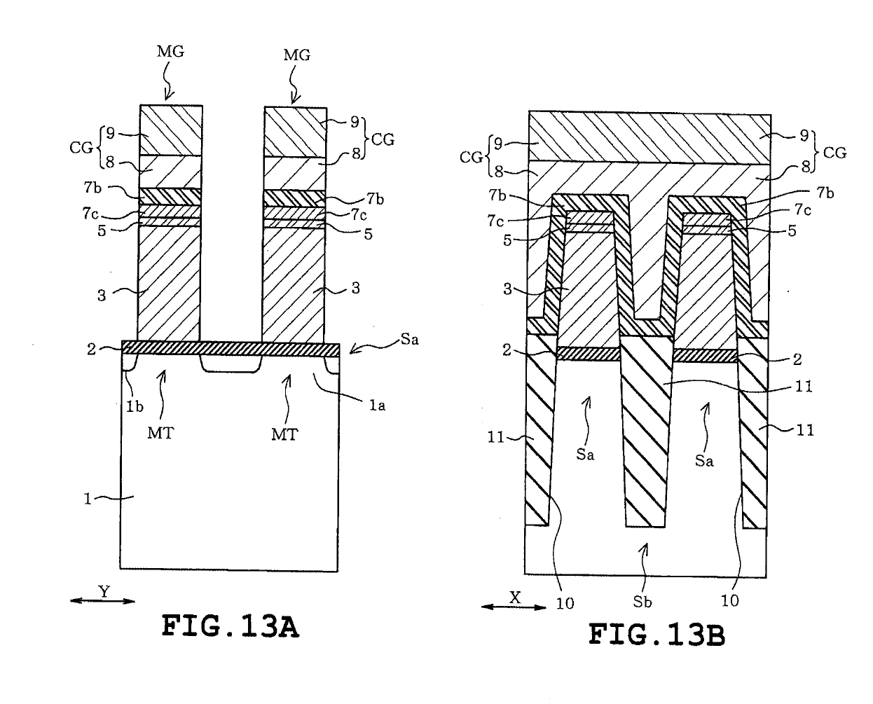

FIG. 13A and FIG. 13B illustrate a fourth embodiment. The structures of the present embodiment, as illustrated in FIG. 13A and FIG. 13B, have a stacked structure above tunnel insulating film 2 in which charge storing layer 3, ruthenium film 5, hafnium aluminate (HfAlO) film 7c, ONO film 7b, polysilicon film 8, and metal film 9 are formed one after another.

In the present embodiment, ruthenium film 5 is formed in contact with the upper surface of charge storing layer 3 and hafnium aluminate film 7c is formed in contact with the upper surface of ruthenium film 5. ONO film 7b is formed above the upper side surfaces of charge storing layer 3, along side surfaces of hafnium aluminate film 7c and ruthenium film 5, above the upper surface of hafnium aluminate film 7c, and above the upper surface of element isolation insulating film 11.

In the fourth embodiment, hafnium oxide film 7a of the second embodiment is replaced by hafnium aluminate film 7c.

The structures illustrated in FIGS. 13A and 13B can be obtained by eliminating the process step for forming silicon nitride film 4 and forming hafnium aluminate film 7c instead of hafnium oxide film 7a in the manufacturing process of the first embodiment.

Because ruthenium film 5 is formed above the upper surface of charge storing layer 3, barrier height φb1 can be increased and thereby obtain the operation effect similar to those of the foregoing embodiments in this structure as well.

### Other Embodiments

In the foregoing embodiments, an example in which ruthenium film 5 is formed above charge storing layer 3 was described. Ruthenium film 5 serving as a metal film may be replaced by a tantalum nitride (TaN) film or a titanium nitride film (TiN) serving as a metal containing film. It is not necessary to form an insulating film between ONO film 7b and ruthenium film 5, tantalum nitride (TaN) film, or titanium nitride (TiN) film.

Hafnium oxide film 7a or hafnium aluminate film 7c may be formed above ruthenium film 5, tantalum nitride (TaN) film, or titanium nitride (TiN) film. Hafnium oxide film 7a and hafnium aluminate 7c may be replaced by a rare-earth oxide film. In such case, hafnium oxide film 7a, or the like, may be replaced by a zirconium oxide (ZrO) film, a lanthanum oxide (LaO) film, or a lanthanum aluminate (LaAlO) film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a semiconductor substrate;
a tunnel insulating film formed above the semiconductor substrate;
a charge storing layer formed above the tunnel insulating film;
a charge storing surface layer film being formed only above an upper surface of the charge storing layer and being provided with a metal film or a metal containing film having a work function higher than a work function of an n-type polysilicon (Si);
an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and
a control electrode formed above the interelectrode insulating film.

2. The nonvolatile semiconductor storage device according to claim 1, wherein the charge storing surface layer film includes a ruthenium (Ru) film serving as the metal film.

3. The nonvolatile semiconductor storage device according to claim 1, wherein the charge storing surface layer film includes a tantalum nitride (TaN) film or a titanium nitride (TiN) film as the metal containing film.

4. The nonvolatile semiconductor storage device according to claim 2, wherein the charge storing surface layer film includes a silicon nitride film between the charge storing layer and the ruthenium film.

5. The nonvolatile semiconductor storage device according to claim 2, wherein the interelectrode insulating film includes a hafnium oxide film disposed directly and only on an upper surface of the ruthenium film of the charge storing surface layer film.

6. The nonvolatile semiconductor storage device according to claim 1, wherein the charge storing surface layer film consists of a ruthenium (Ru) film serving as the metal film.

7. The nonvolatile semiconductor storage device according to claim 1, wherein the charge storing surface layer film consists of a tantalum nitride (TaN) film or a titanium nitride (TiN) film as the metal containing film.

8. The nonvolatile semiconductor storage device according to claim 1, wherein the charge storing surface layer film consists of a ruthenium (Ru) film serving as the metal film, and wherein the interelectrode insulating film includes a hafnium oxide film only above an upper surface of the ruthenium film (Ru) of the charge storing surface layer film.

9. The nonvolatile semiconductor storage device according to claim 1, wherein the interelectrode insulating film includes a rare-earth oxide film formed only above an upper surface of the charge storing layer.

10. The nonvolatile semiconductor storage device according to claim 2, wherein the interelectrode insulating film includes a rare-earth oxide film formed only above an upper surface of the ruthenium film.

11. The nonvolatile semiconductor storage device according to claim 3, wherein the interelectrode insulating film includes a rare-earth oxide film formed only above an upper surface of the tantalum nitride (TaN) film Or the titanium nitride (TiN) film.

12. The nonvolatile semiconductor storage device according to claim 1, wherein the interelectrode insulating film includes either one of hafnium aluminate (HfAlO) film, zirconium oxide (ZrO) film, lanthanum oxide (LaO) film, and lanthanum aluminate (LaAlO) film disposed only above an upper surface of the charge storing layer.

13. The nonvolatile semiconductor storage device according to claim 2, wherein the interelectrode insulating film includes either one of hafnium aluminate (HfAlO) film, zirconium oxide (ZrO) film, lanthanum oxide (LaO) film, and lanthanum aluminate (LaAlO) film disposed only above an upper surface of the ruthenium film.

14. The nonvolatile semiconductor storage device according to claim 3, wherein the interelectrode insulating film includes either one of hafnium aluminate (HfAlO) film, zirconium oxide (ZrO) film, lanthanum oxide (LaO) film, and lanthanum aluminate (LaAlO) film disposed only above an upper surface of the tantalum nitride (TaN) film or the titanium nitride (TiN) film.

15. A nonvolatile semiconductor storage device, comprising:
a semiconductor substrate;
a tunnel insulating film formed above the semiconductor substrate;
a charge storing layer formed above the tunnel insulating film;
a charge storing surface layer film being formed only above an upper surface of the charge storing layer and being provided with a metal film;
an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and
a control electrode formed above the interelectrode insulating film,
side surfaces of the charge storing layer facing the control electrode only via the interlayer insulating film, and
the charge storing surface layer film formed only above an upper surface of the charge storing layer includes a ruthenium (Ru) film serving as the metal film.

16. A nonvolatile semiconductor storage device, comprising:
a semiconductor substrate;
a tunnel insulating film formed above the semiconductor substrate;
a charge storing layer formed above the tunnel insulating film;
a charge storing surface layer film being formed only above an upper surface of the charge storing layer and being provided with a metal containing film;
an interelectrode insulating film being formed above the charge storing surface layer film and being provided with a laminate film being provided with either one of a silicon oxide film, a silicon nitride film, and a silicon oxynitride film, or being provided with two or more of the silicon oxide film, the silicon nitride film, and the silicon oxynitride film; and
a control electrode formed above the interelectrode insulating film,
side surfaces of the charge storing layer facing the control electrode only via the interlayer insulating film, and
the charge storing surface layer film formed only above an upper surface of the charge storing layer includes a tantalum nitride (TaN) film or a titanium nitride (TiN) film as the metal containing film.

17. The nonvolatile semiconductor storage device according to claim 15, wherein the charge storing surface layer film formed only above an upper surface of the charge storing layer includes a silicon nitride film between the charge storing layer and the ruthenium film.

18. The nonvolatile semiconductor storage device according to claim 15, wherein the interelectrode insulating film formed only above an upper surface of the charge storing layer includes a hafnium oxide film disposed directly and only on an upper surface of the ruthenium film of the charge storing surface layer film.

19. The nonvolatile semiconductor storage device according to claim 15, wherein the charge storing surface layer film formed only above an upper surface of the charge storing layer consists of a ruthenium (Ru) film serving as the metal film.

20. The nonvolatile semiconductor storage device according to claim 15, wherein the interelectrode insulating film formed only above an upper surface of the charge storing layer includes a rare-earth oxide film formed only above an upper surface of the ruthenium film.
